(19) United States
(12) Patent Application Publication
(10) Pub. No.: US 2017/0162302 A1
(43) Pub. Date: Jun. 8, 2017

(54) CURRENT DETECTION RESISTOR

(71) Applicant: KOA CORPORATION, Ina-shi, Nagano (JP)

(72) Inventor: Satoshi Chiku, Ina-shi (JP)

(73) Assignee: KOA CORPORATION, Ina-shi, Nagano (JP)

(21) Appl. No.: 15/316,672

(22) PCT Filed: Jun. 8, 2015
(86) PCT No.: PCT/JP2015/066482

§ 371 Date: Dec. 6, 2016

(30) Foreign Application Priority Data
Jun. 17, 2014 (JP) 2014-123993

(51) Int. Cl. H01C 1/148; G01R 19/00; H01C 7/13; H01C 7/06; H01C 7/10

(52) U.S. Cl. CPC H01C 1/148; H01C 7/06; H01C 7/10; H01C 7/13; G01R 19/00

(57) ABSTRACT

Provided is a current detection resistor, which has a jumper function and a low resistance resistor function at the same time. The resistor is a metal plate resistor, which comprises a resistor body consisting of a metal material and a pair of electrodes consisting of a metal material having higher conductivity than the resistor body, wherein the resistor body is bonded between the electrodes. The pair of electrodes comprises a first electrode and a second electrode longer than the first electrode, wherein a slit is formed in the second electrode so that a portion of the second electrode becomes a terminal for voltage detection. The end of the slit does not reach the resistor body. The first electrode and the second electrode are respectively provided with mounting portions connecting to wiring patterns, and the resistor body is formed in the vicinity of the mounting portion of the first electrode.

### TECHNICAL FIELD

The present invention relates to current detection resistors, particularly relating to metal plate resistors, which has a resistor body consisting of a metal material.

### BACKGROUND ART

Current detection resistors are used in various kinds of electrical equipment. Particularly a metal plate resistor includes a resistor body consisting of a metal material, which has a small temperature coefficient of resistance, and a pair of electrodes consisting of a metal material, which has high electrical conductivity, at both ends of the resistor body. According to the metal plate resistors, low resistance value can be obtained, small temperature coefficient of resistance can be obtained, excellent heat radiation property can be obtained, and then large current can be detected with high accuracy. Thus the metal plate resistors are widely used for various kinds of current detections (for example, see Japanese laid open patent publication 2001-291601).

The metal plate resistors are desired to be applicable to various kinds of wiring structures basing on demands for miniaturizations etc. of electrical equipment. If the metal plate resistor includes a jumper device function, which can stride over a wiring or an electronical component, then freedom of the design can be increased.

On the other hand, in case of the metal plate resistors having the structure that a resistor body is disposed between a pair of electrodes consisting of Cu etc., when a low resistance value of the resistor is required to be less than 1 mΩ, it is difficult to make a long distance between the pair of the electrodes (that is, to make a long length of the resistor body) so as to realize such a low resistance value. Therefore the resistor having the jumper function and the low resistance value resistor function at the same time is required to make the length of the resistor body short and the length of the electrode long.

However, Cu, which is widely used as the electrode material, has a large temperature coefficient of resistance such as about 4000 ppm/° C. Thus there becomes a problem that a current detection accuracy of the resistor having the lower resistance value of less than 1 mΩ deteriorates because of influence of a large temperature coefficient of resistance of the Cu.

### SUMMARY OF INVENTION

### Technical Problem

The invention has been made basing on above-mentioned circumstances. Thus an object of the invention is to provide a current detection resistor, which has a jumper function and a low resistance value resistor function at the same time.

### Solution to Problem

The current detection resistor of the present invention is a metal plate resistor that includes a resistor body consisting of a metal material and a pair of electrodes consisting of a metal material, which has higher electrical conductivity than the resistor body. The resistor body is bonded between the pair of the electrodes, which includes a first electrode and a second electrode longer than the first electrode, wherein a slit is formed in the second electrode so that a portion of the second electrode becomes a terminal for voltage detection.

According to the present invention, the length of the resistor body can be short, thus the resistor can be made to be a low resistance value resistor. And by forming a slit in the second electrode so that a portion of the second electrode becomes a terminal for voltage detection, highly accurate current detection becomes possible because of eliminating the influence of the electrode material of Cu, which has a large temperature coefficient of resistance. At the same time the resistor can have a jumper function for mounting to stride over a wiring or an electronic component by the long second electrode.

### BRIEF DESCRIPTION OF DRAWINGS

FIG. 1A is a perspective view of the current detection resistor of first embodiment of the present invention.

FIG. 1B(a) is a plan view, FIG. 1B(b) is a front view, and FIG. 1B(c) is a right side view of the resistor.

FIG. 2 illustrates manufacturing steps of the resistor.

FIG. 3A is a perspective view illustrating the resistor to be mounted on wiring patterns.

FIG. 3B is a perspective view illustrating the resistor to be mounted on the other wiring patterns.

FIG. 4A is perspective views of the resistor of second embodiment of the present invention.

FIG. 4B(a) is a plan view, FIG. 4B(b) is a front view, and FIG. 4B(c) is a right side view of the resistor.

FIG. 5A is a perspective view of the resistor of third embodiment of the present invention.

FIG. 5B(a) is a plan view, FIG. 5B(b) is a front view, and FIG. 5B(c) is a right side view of the resistor.

FIG. 6A is a perspective view of the resistor of fourth embodiment of the present invention.

FIG. 6B(a) is a plan view, FIG. 6B(b) is a front view, and FIG. 6B(c) is a right side view of the resistor.

FIG. 6C is a perspective view of the resistor of fifth embodiment of the present invention.

FIG. 6D(a) is a plan view, FIG. 6D(b) is a front view, and FIG. 6D(c) is a right side view of the resistor.

FIG. 7A is a perspective view of the resistor of sixth embodiment of the present invention.

FIG. 7B(a) is a plan view, FIG. 7B(b) is a front view, and FIG. 7B(c) is a right side view of the resistor.

### DESCRIPTION OF EMBODIMENTS

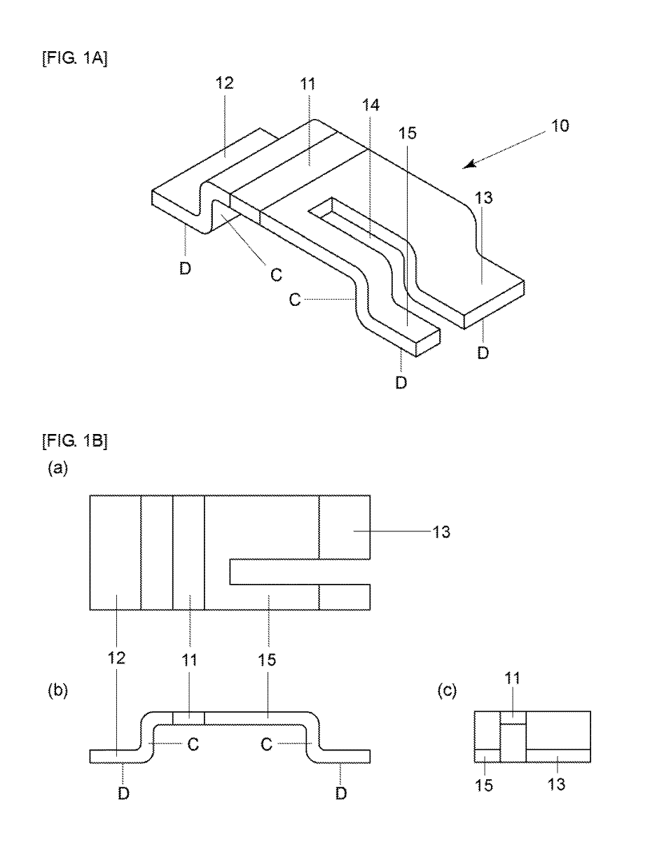

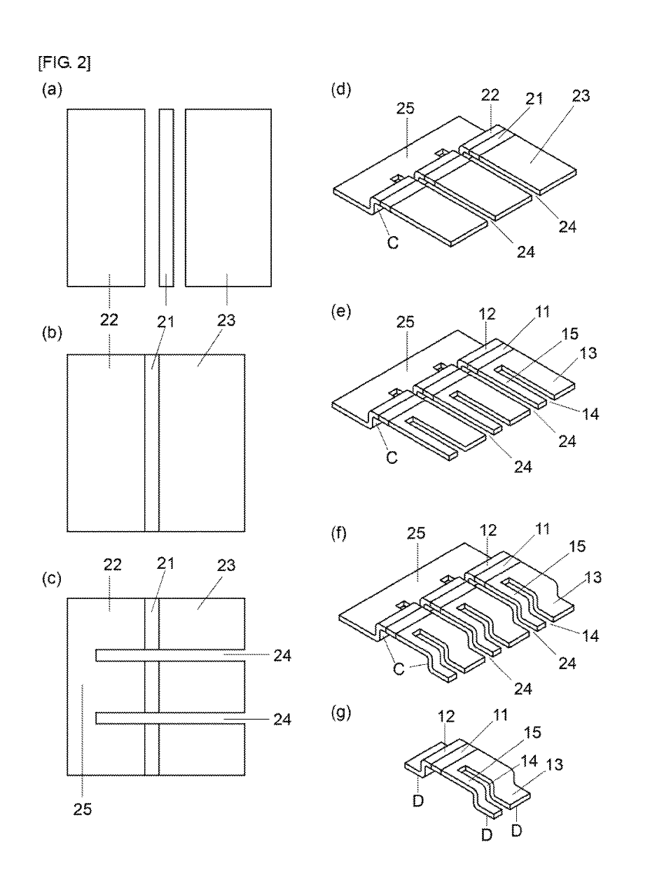

Embodiments of the present invention will be described below with referring to FIG. 1A through FIG. 7B. Like or corresponding parts or elements will be denoted and explained by same reference characters throughout views.

FIGS. 1A-1B illustrate the current detection resistor of first embodiment of the present invention. The resistor is a metal plate resister including a resistor body 11 consisting of a metal material, a pair of electrodes 12,13 consisting of a metal material, which has higher electrical conductivity than the resistor body, and the resistor body 11 is bonded between the pair of the electrodes 12,13. The resistor body 11 is consisting of a metal material such as Cu—Ni system alloy, Cu—Mn—Ni system alloy, Ni—Cr system alloy, or Fe—Cr system alloy, etc. These material has a low specific resistance value and a small temperature coefficient of resistance, and enables to provide a metal plate resistor having a low resistance value and a small temperature coefficient of resistance.

Both ends of the resistor body 11 in direction of the current passing through are bonded with a pair of electrodes 12,13 consisting of a metal material such as Cu etc., which has higher electrical conductivity than the resistor body. The end faces of the resistor body and the electrodes are abut-bonded to form a metal plate resistor. Both of the first electrode 12 and the second electrode 13 is provided with a bent portion C. The second electrode 13 is longer than the first electrode 12 and can stride over a wiring or an electronical component. Thus the resistor 10 is provided with the jumper function.

However the electrode material of Cu has a large temperature coefficient of resistance of about 4000 ppm/C, and then current detection accuracy of the resistor becomes affected when the resistance value of the resistor is low as mentioned before. Thus the pair of electrodes includes a first electrode 12 and a second electrode 13 longer than the first electrode, and a slit 14 is formed in the second electrode 13 so that a portion of the second electrode 13 becomes a terminal 15 for voltage detection.

The end of the slit 14 does not reach the resistor body 11. A distance between the resistor body 11 and the end of the slit 14 is preferably about 0.1-1 mm. Therefore by making a length of the resistor body 11 between the electrodes 12,13 short, a low resistance value resistor can be obtained, and by forming a slit 14 in the second electrode 13 and a portion of the second electrode 13 is made to be a terminal 15 for voltage detection, a current does not flow in the terminal 15 and a voltage near the resistor body 11 can be detected. Thus the current can be detected with high accuracy without the influence of a large temperature coefficient of resistance of the electrode material Cu. That is, a jumper function and a highly accurate current detection function can be existing at the same time.

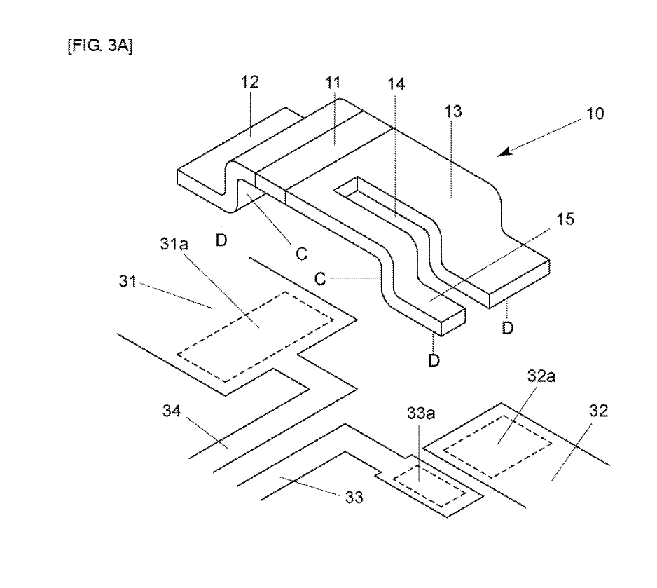

The first electrode 12 and the second electrode 13 are respectively provided with a mounting portion D consisting of a plated solder layer, which connects to wiring patterns 31a,32a,33a (see FIGS. 3A and 3B). The resistor body 11 is disposed near the mounting portion D of the first electrode 12. Because the resistor body 11 is disposed at a position displaced to the electrode 12, heat generated in the resistor body 11 can be easily dissipated to the mounting board through the mounting portion D and the pattern 31a. Thus the resistor 10 can be a current detection resistor excellent in heat dissipation property.

FIG. 2 illustrates a manufacturing process of the resistor 10. First, as shown in FIG. 2(a), a strip-shaped resistive material 21 consisting of a metal material such as Cu—Ni system alloy etc. and strip-shaped electrode materials 22,23 consisting of a high electrical conductivity metal material such as Cu etc. are prepared. Next, as shown in FIG. 2(b), end faces are respectively abut-welded by electron beam welding, laser beam welding etc. Thus raw material of the resistor that electrode materials 22,23 are bonded to both sides of the strip-shaped resistive material 21 is formed.

Next, as shown in FIG. 2(c), slits 24 are formed by dicer etc. for separating into individual pieces. A portion where the slit 24 does not reach becomes a connection portion 25, which commonly connects the individual piece portions. The resistive material 21 and the electrode material 23 separated by the slit 24 become the resistor body 11 and the second electrode 13 later. Next, as shown in FIG. 2(d), bent portions C are formed by first forming. The bent portions are formed by press or roller process.

Next, as shown in FIG. 2(e), slits 14 are formed by dicer etc. for forming terminals 15. Thus the terminals 15 are formed in the second electrode portions 13 for voltage detection. Next, as shown in FIG. 2(f), bent portions C are formed in the second electrodes 13 by second forming. The bent portions C are formed by press or roller process. Next, as shown in FIG. 2(g), the connection portions 25 are cut off and then the resistors 10 have been separated into individual pieces. After then mounting portions D are formed by forming a plated solder layer etc. on mounting surfaces of the electrodes 12,13 of the resistor 10.

FIG. 3A illustrates an example of wiring patterns on a mounting board. The example is a case that the resistor 10 is used for current detection. The wiring pattern 31 is provided with a land 31a, on which first electrode 12 of the resistor 10 is fixed, and the wiring pattern 32 is provided with a land 32a, on which second electrode 13 of the resistor 10 is fixed. Therefore the heat generated in the resistor body 11 is mainly dissipated to the mounting board through the land 31a and the electrode 12, which is disposed near the resistor body 11.

The wiring pattern 33 for voltage detection is provided with a land 33a, on which voltage detection terminal 15 is fixed, and the other wiring pattern 34 for voltage detection is connected to the wiring pattern 31. The current to be detected passes through the wiring pattern 31, the electrode 12, the resistor body 11, the electrode 13, and the wiring pattern 32. The voltage caused by the current between both ends of the resistor body 11 is detected by a voltage detection device (not shown in the figure) through the wiring patterns 33,34.

FIG. 3B also illustrates another example of wiring patterns on the mounting board. The example is a case that the resistor 10 is used for a jumper device striding over the component 35 such as an electronic component. Even though striding over the component 35 etc. with the long electrode 13, it is possible to detect the current with high accuracy while working as a jumper device because of the voltage detection terminal 15 separated by the slit 14. The resistor body 11 that is a heat generation source, can be disposed avoiding over the component 35, then influence of the resistor body 11 as the heat source can be decreased.

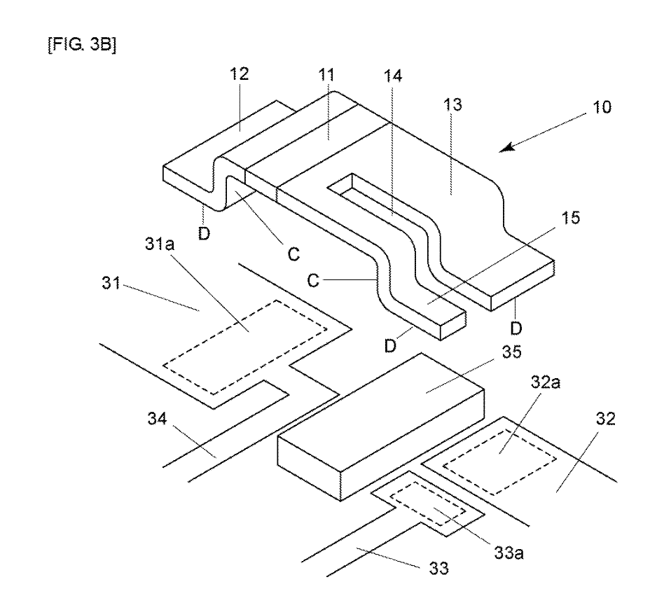

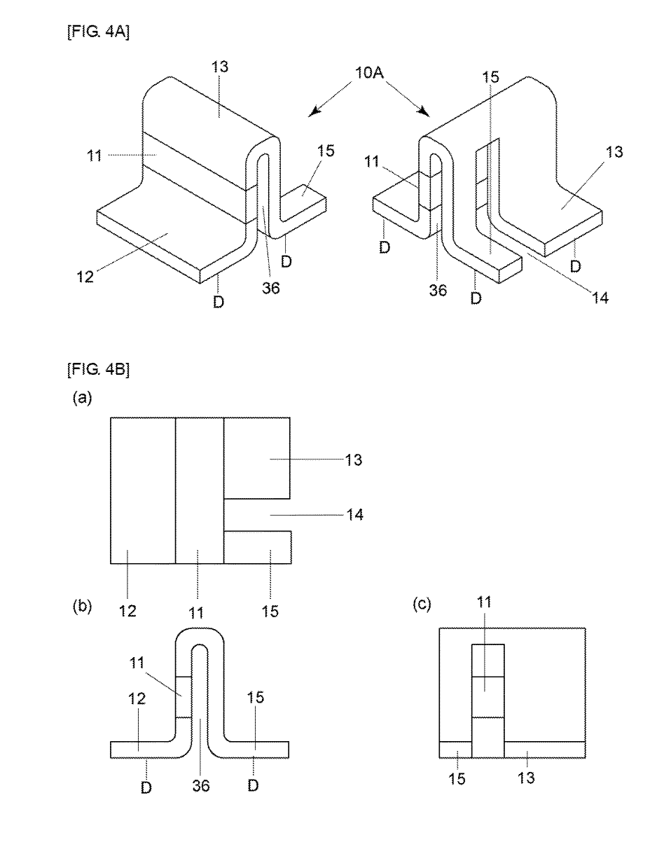

FIGS. 4A-4B illustrate the resistor 10A of second embodiment of the present invention. In the embodiment, the second electrode 13 is turned as shown in the figure, then the resistor 10A is less likely to be affected by the inductances. The electrode 13 is longer than the other electrode 12, however the slit 14 reaches near the resistor body 11, and then the highly accurate current detection becomes possible as mentioned before.

It is preferable to fill a resin having excellent thermal conductivity into a space 36 between the resistor body 11 and the second electrode 13. Therefore the heat generated in the resistor body 11 can be dissipated through not only the first electrode 12 side but also the second electrode 13 side and the voltage detection terminal 15 side to the mounting board. Further since the resistor body 11 expands and shrinks vertically by the heat generation, the resistor 10A has an advantage that the stress to the solder bonded portion with the electrode 12 and the electrode 13 is less likely caused.

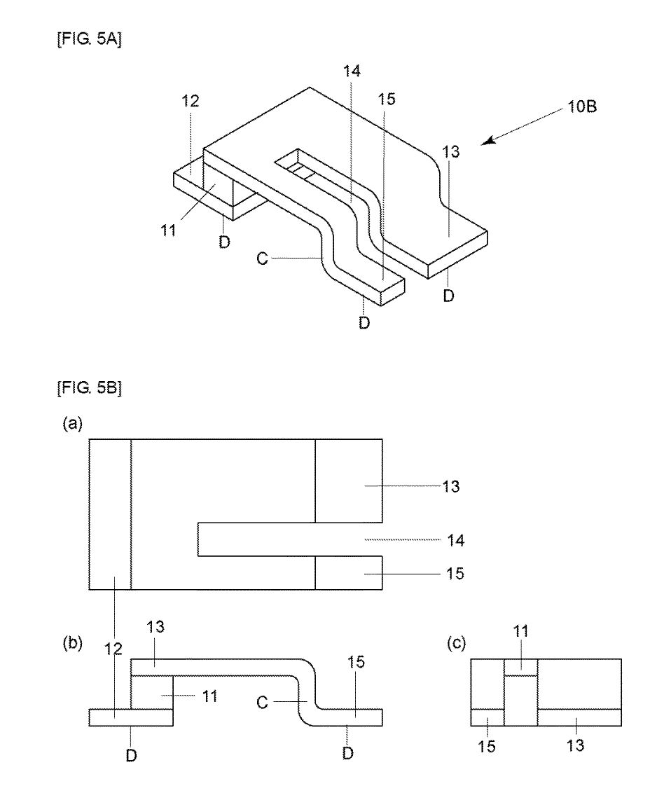

FIGS. 5A-5B illustrate the resistor 10B of third embodiment of the present invention. In the embodiment, the resistor body 11 is superposed and bonded between an end of the first electrode 12 and an end of the second electrode 13. That is, one step is formed at a portion where the first electrode 12, the resistor body 11, and the second electrode 13 are superposed, and the other step is formed at bent portion C in the second electrode 13. Thus the resistor 10B has the jumper device function, which strides over a wiring or a component, with the low resistance value resistor function.

Therefore the length of the resistor body 11 in direction of the current passing through can be shortened (that is, the length can be the thickness of the resistor body 11), and the area of the resistor body 11 perpendicular to the current passing through direction can be large. Then lower resistance value of the resistor 10B such as less than 100 μΩ can be realized. Because of the slit 14 reaching near the resistor body 11, highly accurate current detection becomes possible as well as before mentioned embodiments. Further because of the resistor body 11 disposed on the first electrode 12, heat dissipation to the mounting board is also excellent.

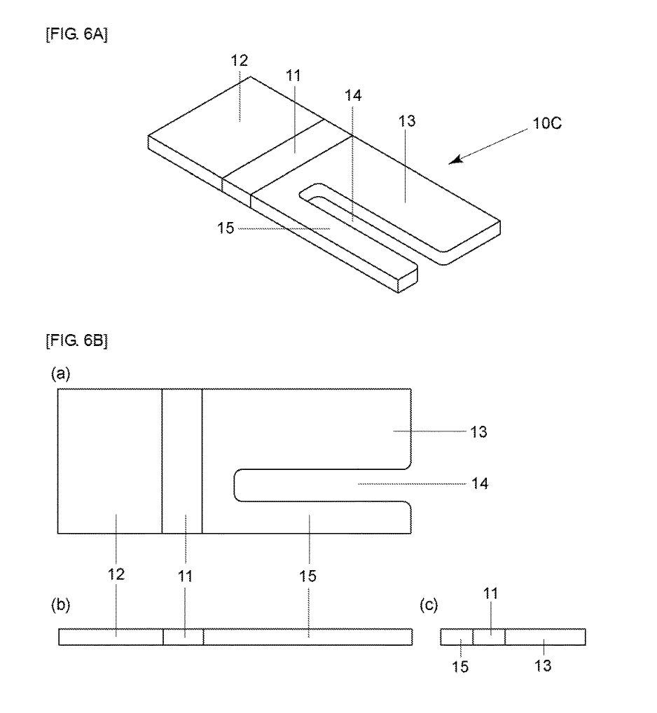

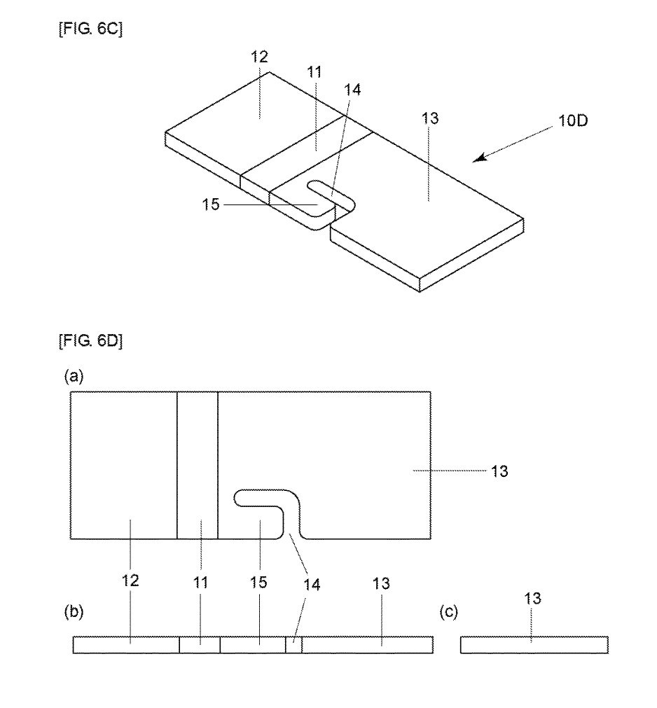

FIGS. 6A-6B illustrate the resistor 10C of fourth embodiment of the present invention. The resistor 10C is flat plate shaped without any step such as bent portion C etc. The slit 14 is formed in the second electrode 13 as well as before mentioned embodiments and a portion of the second electrode becomes a terminal 15 for voltage detection.

FIGS. 6C-6D illustrate the resistor 10D of fifth embodiment of the present invention. The resistor 10D is also flat plate shaped without any step such as bent portion C etc. The slit 14 is formed to extend inwardly from a side face of the second electrode 13 and to be bent to reach near the resistor body 11. Thus while detecting a voltage near the resistor body 11 in the second electrode 13 by the voltage detection terminal 15, the area of the second electrode 13 can be made large.

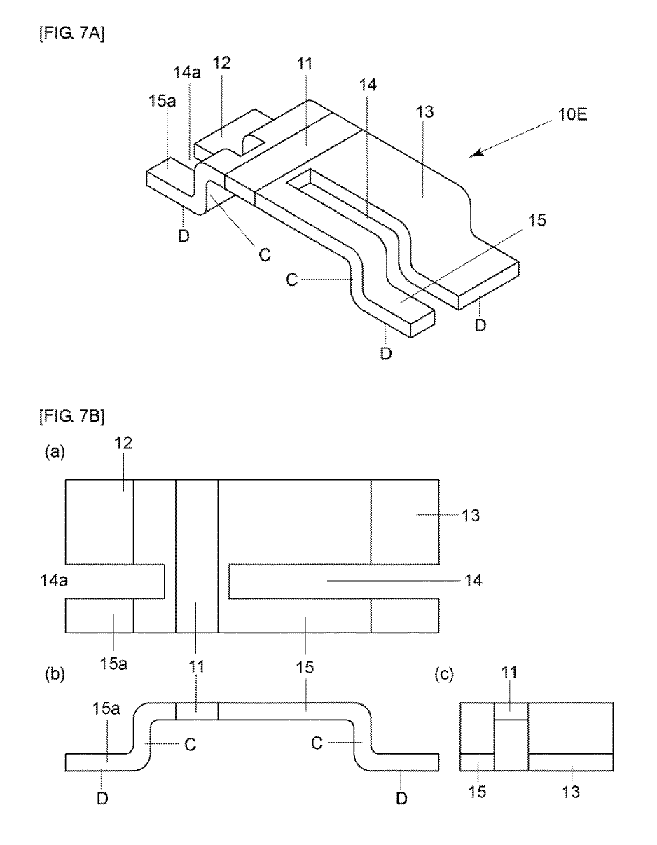

FIGS. 7A-7B illustrate the resistor 10E of a variation of first embodiment of the present invention. The resistor 10E is further provided with the slit 14a in the first electrode 12 and the voltage detection terminal 15a in the first electrode 12. Thus an influence of a large temperature coefficient of resistance of Cu etc. can be further decreased in the first electrode 12 and more highly accurate voltage detection becomes possible.

Although embodiments of the present invention have been explained, however the invention is not limited to above embodiments, and various changes and modifications may be made within scope of the technical concepts of the invention.

### INDUSTRIAL APPLICABILITY

The present invention can be suitably used for the current detection resistors, which has a jumper function and a highly accurate current detection function at the same time, and particularly can be suitably used for the metal plate resistors.

1. A current detection resistor, comprising:
a resistor body consisting of a metal material;
a pair of electrodes consisting of a metal material, which has higher electrical conductivity than the resistor body, the resistor body being bonded between the electrodes to form a metal plate resistor;
wherein the pair of electrodes comprises a first electrode and a second electrode longer than the first electrode, and a slit is formed in the second electrode so that a portion of the second electrode becomes a terminal for voltage detection.

2. The resistor of claim 1, wherein an end of the slit does not reach the resistor body.

3. The resistor of claim 1, wherein the first electrode and the second electrode are respectively provided with mounting portions for connecting to wiring patterns, and the resistor body is formed in the vicinity of the mounting portion of the first electrode.
